(19) United States
(12) Patent Application Publication
(10) Pub. No.: US 2017/0054052 A1
(43) Pub. Date: Feb. 23, 2017

(54) APPARATUS AND METHOD FOR IMPROVING EFFICIENCY OF THIN-FILM PHOTOVOLTAIC DEVICES

(71) Applicant: FIRST SOLAR, INC, Perrysburg, OH (US)

(72) Inventors: Markus Gloeckler, Perrysburg, OH (US); Akhlesh Gupta, Sylvania, OH (US); Xilin Peng, Bloomington, MN (US); Rick C. Powell, Ann Arbor, MI (US); Jigish Trivedi, Perrysburg, OH (US); Jianjun Wang, Perrysburg, OH (US); Zhibo Zhao, Novi, MI (US)

(21) Appl. No.: 15/342,533

(22) Filed: Nov. 3, 2016

Related U.S. Application Data
(63) Continuation of application No. 13/899,153, filed on May 21, 2013, now abandoned.
(60) Provisional application No. 61/649,680, filed on May 21, 2012.

(51) Int. Cl. H01L 31/18; H01L 31/0216; H01L 31/0236; H01L 31/0296; H01L 31/073

(52) U.S. Cl. CPC H01L 31/1864; H01L 31/0296; H01L 31/073; H01L 31/02363; H01L 31/02167

(57) ABSTRACT

A method for producing, apparatus for producing and photovoltaic device including semiconductor layers with halide heat treated surfaces that increase grain growth within at least one of the semiconductor layers and improve the interface between the semiconductor layers. The halide heat treatment includes applying and heating multiple coatings of a halide compound on surfaces adjacent to or part of the semiconductor layers.

This application is a continuation of U.S. patent application Ser. No. 13/899,153, filed May 21, 2013, which claims the benefit of priority of U.S. Provisional Patent Application No. 61/649,680, filed May 21, 2012, entitled: “Apparatus and Method for Improving Efficiency of Thin-Film Photovoltaic Devices” the entirety of which are incorporated by reference herein.

### FIELD OF THE INVENTION

Disclosed embodiments relate generally to photovoltaic devices, and more particularly, to an apparatus for and a method of improving efficiency of thin-film photovoltaic devices.

### BACKGROUND OF THE INVENTION

Photovoltaic devices can include semiconductor material deposited over a substrate such as glass, for example, with a first layer of the semiconductor material serving as a window layer and a second layer of the semiconductor material serving as an absorber layer. The semiconductor window layer forms a junction with the semiconductor absorber layer where incident light is converted to electricity. During operation, light passes through the photovoltaic device and is absorbed by electrons at or near this junction. This produces photo-generated electron-hole pairs, where the electron acquires sufficient energy to “move” to an elevated state, leaving behind a hole. A built in electric field promotes the movement of these photo-generated electron-hole pairs, which produces electric current that can be output to other electrical devices.

One limiting factor on thin-film photovoltaic device efficiency is the reduced lifetime of the photo-generated electron hole pairs when they are in the semiconductor absorber layer. This is called reduced carrier lifetime. Carrier lifetime is calculated as the average time it takes electrons in an absorber layer to lose their excited energy by recombining with a paired hole. Recombination may also occur near structural defects such as grain boundaries in polycrystalline materials. To increase carrier lifetime in the absorber layer, it is desirable to increase absorber layer grain size, the average size of merged semiconductor particles in a semiconductor layer. Increasing absorber layer grain size occurs through grain growth (the merging of these semiconductor particles within the semiconductor layer). The greater the grain size of the semiconductor particles, the more difficult it is for excited electrons associated with the particles to lose their excited energy by recombination or the longer the carrier lifetime of the semiconductor particles. Increased carrier lifetime of semiconductor particles in the semiconductor layer increases photovoltaic device efficiency because the fewer excited electron-hole pairs will be lost in an undesirable recombination event.

In order to improve the efficiency of thin-film photovoltaic devices, the semiconductor absorber layer is often subjected to a cadmium chloride heat-treatment to promote grain growth. Cadmium chloride heat-treatments include applying a cadmium chloride compound to an exposed surface of a deposited semiconductor absorber layer and then heating the layer. The heat helps the cadmium chloride diffuse into the semiconductor absorber layer where it interacts with the semiconductor particle promoting their merger into larger particle, which is absorber layer grain growth. However, this treatment only promotes absorber layer grain growth of 1 to 2 um, providing only a limited improvement of carrier lifetime in the absorber layer. After the completion of the heat-treatment, a surface cleaning step may be performed to remove residue of the halide coating and byproducts of the annealing process such as oxide phases formed from the semiconductor material or the halide material.

Accordingly, a method and apparatus for producing an absorber layer grain growth of more than 2 um as well as improving the interface between the semiconductor absorber layer and the semiconductor window layer when the semiconductor window layer has been thinned out enough to reduce optical loss are desirable.

### BRIEF DESCRIPTION OF THE DRAWINGS

FIG. 1 is a schematic of a photovoltaic device having multiple layers;

FIG. 2 is a schematic showing the location of a halide coating in a photovoltaic device having multiple layers;

FIGS. 3A-3C are schematics showing the location of halide coatings in a photovoltaic device having multiple layers;

FIG. 4 is a schematic showing the location of halide coatings in a photovoltaic devices having multiple layers;

FIG. 5 is a diagram of an apparatus for producing semiconductor layers with halide coated surfaces in a photovoltaic device;

FIG. 6 is a diagram of an apparatus for producing semiconductor layers with halide coated surfaces in a photovoltaic device; and

FIG. 7 is a schematic of a photovoltaic device.

### DETAILED DESCRIPTION OF THE INVENTION

In the following detailed description, reference is made to the accompanying drawings which form a part hereof, and which illustrate specific embodiments of the invention. These embodiments are described in sufficient detail to enable those of ordinary skill in the art to make and use them. It is also understood that structural, logical, or procedural changes may be made to the specific embodiments disclosed herein without departing from the spirit or scope of the invention.

A method for producing semiconductor thin-film layers in a photovoltaic device is provided. The method includes depositing a thin-film semiconductor window layer and a thin-film semiconductor absorber layer or multiple semiconductor absorber layers over a substrate, then applying a halide heat treatment. The halide heat treatment includes applying a first coating of a halide compound on at least one surface of the semiconductor absorber layer or layers, heat-treating the surface to activate the halide compound applied thereon, providing at least a second coating of the halide compound on the at least one surface and heat-treating the surface once more. The second heat-treatment may occur under the same or different ambient conditions than the first heat-treatment. For example, the temperature used in the second heat-treatment may differ from that of the first heat-treatment and/or ambient atmospheric conditions under which the first treatment occurred may differ from those of the second heat-treatment.

In accordance with the provided method, the halide compound that diffuses into the absorber layer chemically interacts with the crystalline structure of the layer. The repetition of this interaction during the multiple halide applications and heatings facilitates better combination and recrystallization of the molecules of the semiconductor absorber material than when the halide compound is not present or only applied in a single application.

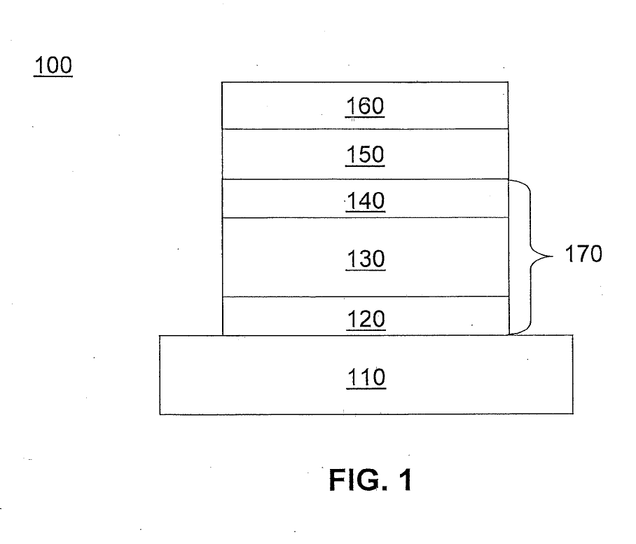

As shown in FIG. 1, where an exemplary photovoltaic device 100 is depicted, a plurality of layers are used in fabricating the device. For example, a TCO stack 170 may be deposited on the glass substrate 110. The TCO stack 170 may include a barrier layer 120, a TCO layer 130, and a buffer layer 140. The barrier layer 120 may be made of various materials, which include silicon nitride, silicon oxide, aluminum-doped silicon oxide, boron-doped silicon nitride, phosphorus-doped silicon nitride, silicon oxide-nitride, or any combination thereof. The barrier layer is used to prevent any contaminants from substrate 110 from diffusing into other layers of the photovoltaic device. The TCO layer 130 is used as a front contact and may be made of materials containing tin oxide or cadmium tin oxide. The buffer layer 140 may be made of various materials, including tin oxide (e.g., a tin (IV) oxide), zinc tin oxide, zinc oxide, zinc oxysulfide, and zinc magnesium oxide.

Further, semiconductor layers may be deposited on the TCO stack 170. The semiconductor layers may include a semiconductor window layer 150, which may be made of cadmium sulfide, and a semiconductor absorber layer 160 made of cadmium telluride. Both the semiconductor window layer 150 and semiconductor absorber layer 160 can be deposited using any known deposition technique, including vapor transport deposition (VTD).

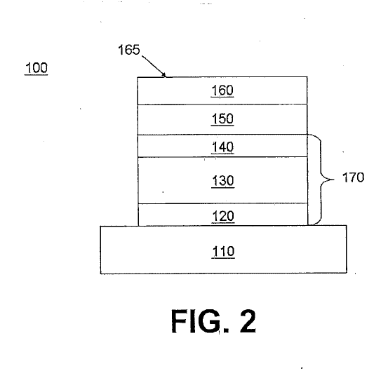

In FIG. 2, a halide compound is shown to have been applied to an exposed surface of the semiconductor absorber layer 160 of FIG. 1 to form a halide coated surface 165. The halide heat treatment that forms the halide coated surface 165, as shown in FIG. 2, may include applying a first coating of a halide compound on the surface 165, heating the coated surface 165 to activate the halide compound, then applying at least a second coating of the halide compound on the same surface 165 and heating the halide coated surface 165 under the same or different conditions prior to any further thin-film layer deposition. The halide coating applied to the surface 165 may be solid/powder applied in liquid form by a liquid spray dispenser or an aqueous salt solution that is vaporized and applied in a gaseous form through, for example, a vapor transport deposition apparatus. The halide compound may include CdCl₂, MnCl₂, MgCl₂, ZnCl₂, NH4Cl, TeCl₄, HCl or NaCl. After completion of the first or second step, the surface may undergo a cleaning process to remove residuals of the halide coating or byproducts of the process.

The heatings of the halide coated surface 165 after each halide coatings may be performed at temperatures, for example, temperatures T1 after applying the first halide coating and T2 after applying the second halide coating, in the range of about 350° C. to about 600° C. for durations of time, for example D1 after the first halide coating and D2 after the second halide coating, in the range of about 1 minute to about 60 minutes. In various embodiments, temperature T1 may be less than temperature T2, temperature T1 may be greater than temperature T2, or temperature T1 may be equal to temperature T2. Similarly, duration D1 may be equal to duration D2, duration D1 may be less than duration D2, or duration D1 may be greater than duration D2. For example, after the first coating of the halide compound is applied to the desired surface adjacent to or part of the semiconductor layers, the surface may be heated to a first temperature of about 450° C. for a duration of about 10 minutes. Then, after the second coating of the halide compound is applied to the same surface, the surface may be heated again to a second temperature of about 420° C. for a duration of about 10 minutes. In another embodiment, after the first coating of the halide compound is applied to the desired surface adjacent to or part of the semiconductor layers, the surface may be heated to a first temperature of about 450° C. for a duration of about 10 minutes. Then, after the second coating of the halide compound is applied to the same surface, the surface may be heated again to a second temperature of about 500° C. for a duration of about 30 minutes.

Heating the halide coatings at lower temperatures promotes incorporation of the halide into the semiconductor layer while heating the halide treatments at higher temperature drives the formation of the crystalline structure, increasing grain growth. So, heating the halide coatings first at a lower temperature and then second at a higher temperature, for example, where temperature T1 may be less than temperature T2, will first promote incorporation of the halide into the semiconductor layer and then drive the formation of the crystalline structure in the presence of the halide to increase grain growth. Alternatively, heating the halide coatings first at a higher temperature and then second at a lower temperature, for example, where temperature T1 may be greater than temperature T2, will first drive the formation of the crystalline structure in the presence of the halide and then promote incorporation of optimum levels of halide in the newly formed crystalline structure. Heating the halide coatings multiple times at the same temperature can achieve both effects for longer durations of time without favoring the formation of the crystalline structure over incorporation of the halide compound into the layer.

The heatings of the halide coated surface 165 after each halide coating may be performed under various ambient atmospheric conditions. For example, the ambient atmosphere may include oxygen, or be oxygen depleted; it may contain sulfur or be sulfur free. An ambient atmosphere that includes oxygen promotes the interaction of the halide compound with the semiconductor layer. For an ambient atmosphere containing oxygen, oxygen may be supplied in the processing chamber.

In another embodiment, after application of the first or second halide coating a sulfur containing ambient may be created around the halide coated surface 165 by supplying a sulfur containing gas, for example, hydrogen sulfide, around the halide coated surface 165. A sulfur containing ambient is especially beneficial for the formation of cadmium telluride thin-film layers, as sulfur has been found to interact well with a halide and cadmium telluride to promote grain growth. For an ambient atmosphere containing sulfur, sulfur may be supplied in the processing chamber.

In another embodiment, after application of the first or second halide coating, an oxygen or sulfur depleted ambient may be created around the halide coated surface 165 by using a vacuum to remove all gas from around the halide coated surface 165 or by supplying an inert gas, for example, nitrogen gas, around the halide coated surface 165. The absence of oxygen or sulfur is beneficial in situations where another processing gas is necessary, for example a sulfur gas and the presence of oxygen would interfere with the function of the additional process gas. The absence of oxygen may also be beneficial in a halide diffusions step where no grain growth is intended because it can minimize oxidation of the halide coated surface 165.

The ambient conditions for the multiple post-application heatings may be the same or different. For example, in one embodiment, after application of the first halide coating, a first post-application heating may be performed in an oxygen containing ambient and after application of the second halide coating, a second post-application heating may be performed in an oxygen depleted ambient. In another embodiment, after application of the first halide coating, a first post-application heating may be performed in an oxygen depleted ambient and after application of the second halide coating, a second post-application heating may be performed in an oxygen containing ambient. In another embodiment, after application of the first halide coating a first post-application heating may be performed in a sulfur containing ambient and after application of the first or second halide coating, a second post-application heating may be performed in a sulfur depleted ambient. In another embodiment, after application of the first halide coating, a first post-application heating may be performed in a sulfur depleted ambient and after application of the second halide coating, a second post-application heating may be performed in a sulfur containing ambient.

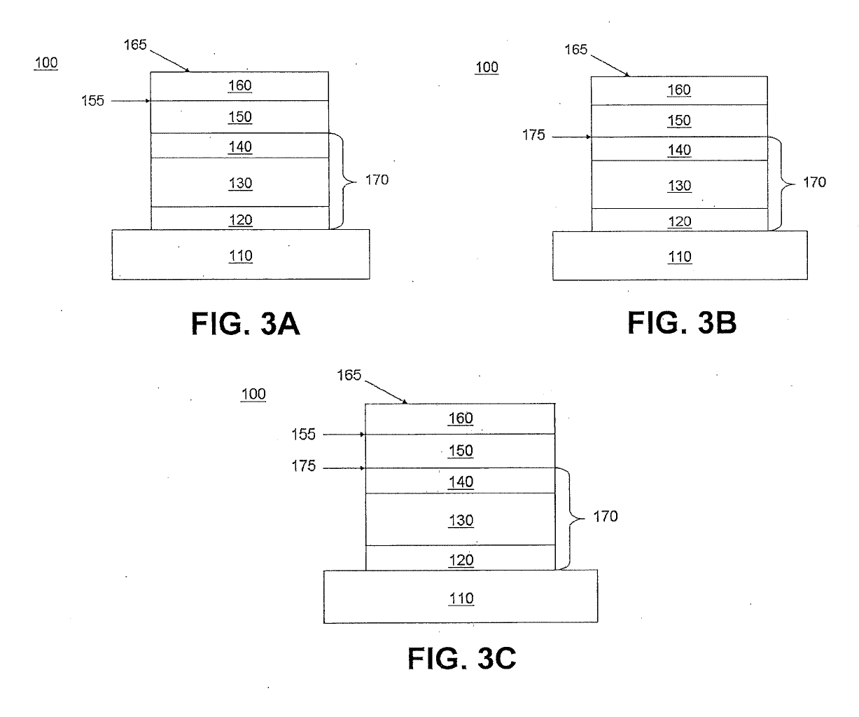

In another embodiment, a single coating of a halide compound may be applied to multiple surfaces between multiple layers adjacent to or part of the semiconductor layers. For example, as shown in FIG. 3A, a single coating of halide compound may be applied to an open surface of a previously deposited semiconductor window layer 150 and heated to fowl a halide coated surface 155. Then, a semiconductor absorber layer 160 may be deposited over the coated surface 155. A full halide heat treatment that includes applying a first halide coating to a surface of the semiconductor absorber layer, heating the coating, applying a second halide coating to the same surface and heating the second coating, may then be performed on the semiconductor absorber layer. For example, as shown in FIG. 3A, a halide heat treatment may be applied to an open surface of the semiconductor absorber layer 160 to form a halide coated surface 165. The halide heat treatment of the semiconductor absorber layer 160 may include applying a first halide coating on the surface of the semiconductor absorber layer 160, heating the coating, applying a second halide coating to the same surface and heating the second coating. It should be noted that in an alternative embodiment, the single coating of halide compound applied to the open surface of the previously deposited semiconductor window layer 150 may be applied without heating prior to deposition of the semiconductor absorber layer 160.

In another embodiment, as shown in FIG. 3B, a single coating of halide compound may be applied to an open surface of a previously deposited TCO stack 170 and heated to form a halide coated surface 175. A semiconductor window layer 150 may be deposited over the halide coated surface 175. A semiconductor absorber layer 160 may be deposited on the semiconductor window layer 150. Then, a full halide heat treatment may be applied to an open surface of the semiconductor absorber layer 160 to form a halide coated surface 165. The halide heat treatment of the semiconductor absorber layer 160 may include applying a first halide coating on the surface of the semiconductor absorber layer 160, heating the coating, applying a second halide coating to the same surface and heating the second coating. Again, it should be noted that in an alternative embodiment, the single coating of halide compound applied to the open surface of the previously deposited TCO stack 170 may be applied without heating prior to deposition of the semiconductor window layer 150.

In another exemplary embodiment, as shown in FIG. 3C, a single coating of halide compound may be applied to an open surface of a previously deposited TCO stack 170 and heated to form a halide coated surface 175. A semiconductor window layer 150 may be deposited over the halide coated surface 175 and another single coating of halide compound may be applied to an open surface of the semiconductor window layer 150 and heated to form a halide coated surface 155. A semiconductor absorber layer 160 may be deposited over the coated surface 155. Then a full halide heat treatment may be applied to an open surface of the semiconductor absorber layer 160 to form a halide coated surface 165. The halide heat treatment of the semiconductor absorber layer 160 may include applying a first halide coating on the surface of the semiconductor absorber layer 160, heating the coating, applying a second halide coating to the same surface and heating the second coating. It should be noted that in an alternative embodiment, the single coating of halide compound applied to the open surface of the previously deposited TCO stack 170 may be applied without heating prior to deposition of the semiconductor window layer 150 and the single coating of halide compound applied to the open surface of the previously deposited semiconductor window layer 150 may be applied without heating prior to deposition of the semiconductor absorber layer 160.

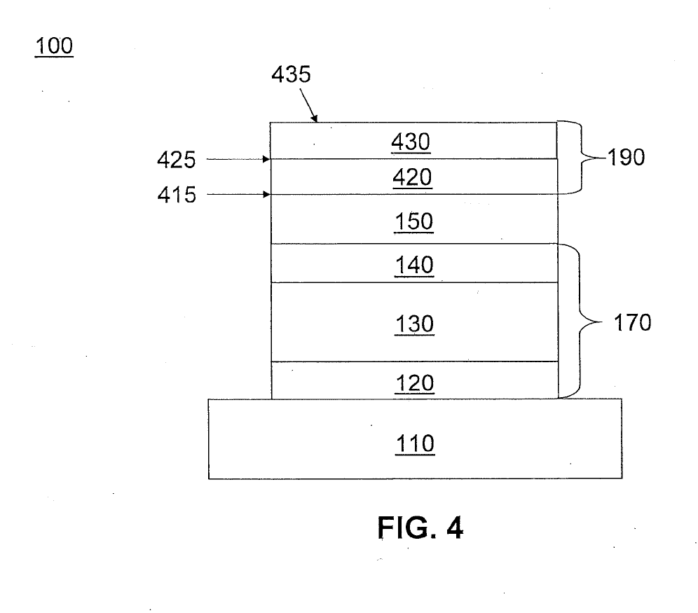

In another embodiment, successive layers of the same semiconductor material may be deposited with halide coated surfaces in between each layer. The combined layers of the same semiconductor material form a combined semiconductor layer. For example, as shown in FIG. 4, a semiconductor window layer 150 may be deposited on TCO stack 170, which has previously been deposited on a substrate 110. A single coating of halide compound may be applied to a surface of the semiconductor window layer 150 and heated to create a halide coated surface 415. Then a first semiconductor absorber layer 420 may be deposited over the halide coated surface 415. Another single coating of halide compound may be applied to a surface of the first semiconductor absorber layer 420 and heated to create a halide coated surface 425. Then a second semiconductor absorber layer 430 may be deposited over the halide coated surface 425. A full halide heat treatment may be applied to a surface of the second semiconductor absorber layer 430 to create a halide coated surface 435. The halide heat treatment of the semiconductor absorber layer 430 may include applying a first halide coating on the surface of the semiconductor absorber layer 430, heating the coating, applying a second halide coating to the same surface and heating the second coating. The first and second semiconductor absorber layers 420, 430 make up a semiconductor absorber layer stack 190 with halide coated surfaces 415, 425, and 435 laced through out the semiconductor absorber layers 420, 430. Again, it should be noted that in an alternative embodiment, the single coating of halide compound applied to the open surface of the previously deposited semiconductor window layer 150 may be applied without heating prior to deposition of the first semiconductor absorber layer 420 and the single coating of halide compound applied to the open surface of the previously deposited semiconductor absorber layer 420 may be applied without heating prior to deposition of the second semiconductor absorber layer 430.

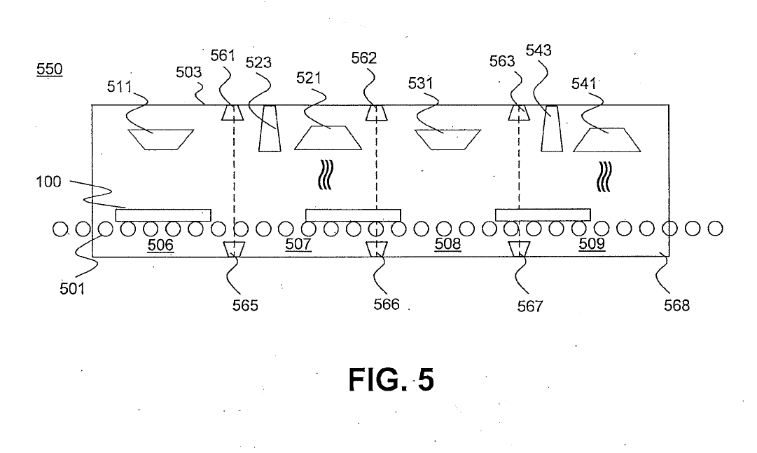

FIG. 5 illustrates a representative apparatus for applying a halide heat treatment to at least one surface adjacent to or part of the cadmium telluride semiconductor layer 160 of a photovoltaic device 100 as shown in FIG. 2. A treatment system 550 which provides for applying a halide heat treatment may include a transporting conveyor system 501, for example, a roller conveyor, for photovoltaic device 100 into and through a chamber 503, which may include at least four discrete processing modules designed for specific purposes. The modules include a first halide application module 506, a first heating module 507, a second halide application module 508, and a second heating module 509.

The conveyor system 501 may transport the photovoltaic device 100 with the cadmium sulfide layer 150 and the cadmium telluride layer 160 as shown in FIG. 2 into the first halide application module 506, which may include a dispenser 511 for applying a coating of a halide compound on the surface of the photovoltaic device 100. The dispenser 511 may be any dispenser apparatus desired to apply the coating of the halide compound to the surface, for example, if the halide is an aqueous salt solution, the dispenser may be a liquid spray dispenser. The photovoltaic device 100 is then transported by conveyor system 501 into the first heating module 507, which may heat the halide coating on the surface of the photovoltaic device 100 to a desired temperature, for example, in the range of about 350° C. to about 600° C. The heat can be supplied by various methods, including resistive heating, convective heating, and radiated heating, as indicated by heater 521. The heating element can be encased in a stainless steel sleeve that is hermetically sealed. A second halide coating may be applied on the previously halide coated surface of the photovoltaic device 100 in the second halide application module 508, which may include a second dispenser 531 for dispensing the halide compound. Then the photovoltaic device 100 is transported by conveyor system 501 into the second heating module 509, which may heat the second halide coating on the surface of the photovoltaic device 100 to a desired temperature, for example, in the range of about 350° C. to about 600° C. using a heater 541. Then the halide coated photovoltaic device 100 may be transported out of the treatment system for subsequent processing to complete production of the photovoltaic device 100.

It should be noted that the treatment system 550 may be placed in sequence before or after other known fabrication systems responsible, for example, for depositing the thin film layers on the substrate 110 of the photovoltaic device 100 as shown in FIG. 2 or for completing subsequent processing of the photovoltaic device 100 after application of the halide heat treatment.

Referring back to FIG. 5, first and second heating modules 507, 509 may further include gas injection ports 523, 543 for providing gas that may create a desired ambient atmosphere at the halide coated surface of the photovoltaic device 100 during the first and second post-halide application heatings. If, for example, an oxygen containing ambient is desired, gas injection ports 523, 543 may provide an oxygen containing gas, for example, compressed dry air, at the surface of the photovoltaic device 100 during the post-application heatings. Alternatively, if a sulfide containing ambient is desired, gas injection ports 523, 543 may provide a sulfur containing gas, for example, hydrogen sulfide, at the halide coated surface of the photovoltaic device 100 during the post-application heatings. If an oxygen or sulfur depleted ambient is desired, the gas injection ports 523, 543 may provide an inert gas, for example, nitrogen gas, at the halide coated surface of the photovoltaic device 100 during the post-application heatings.

Additionally, inert gas introduction ports 561, 562, 563, and corresponding exhaust ports 565, 566, 567, may be placed at the intersections between modules 506 and 507, modules 507 and 508, and modules 508 and 509 to produce inert gas curtains around the first and second heater modules 507 and 509. Inert gas introduction ports 561, 562, 563 will provide a flow of inert gas into the chamber 503 which will then be pulled out of the chamber 503 through corresponding exhaust ports 565, 566, 567 creating a flowing stream of inert gas between the modules 506, 507, 508, 509 which may maintain the ambient conditions within the heating modules 507, 509.

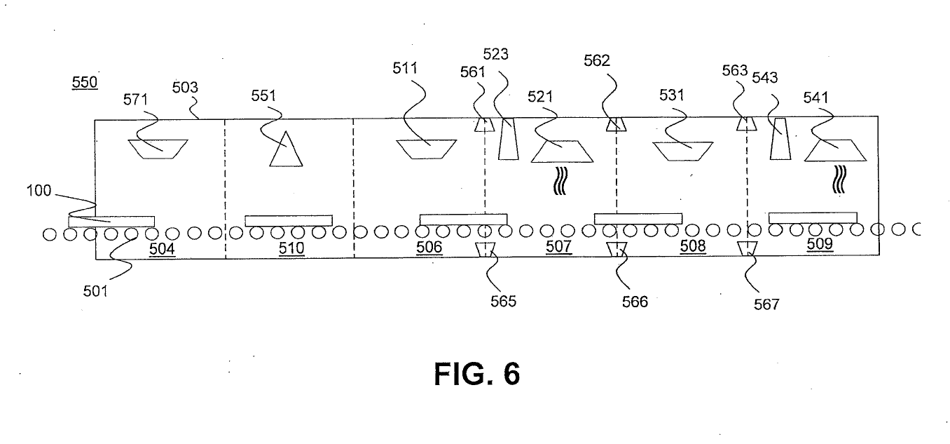

In alternative embodiments, the treatment system 550 may farther include a deposition module 510 and an additional halide application module 504 placed in sequence with the modules 506, 507, 508, 509 of the treatment system 550 to produce a photovoltaic device 100 as shown in FIG. 3A. For example, as shown in FIG. 6, in one exemplary embodiment, a halide application module 504 and a deposition module 510 may be place before the halide application module 506. The conveyor system 501 may transport a photovoltaic device 100 with a TCO stack 170 formed on a substrate 110 and a semiconductor window layer 150 formed on the TCO stack 170 into the halide application module 504, which may include a dispenser 571 for applying a coating of a halide compound on a surface of the photovoltaic device 100, forming a halide coated surface 155 of the semiconductor window layer 150 as shown in FIG. 3A. The photovoltaic device 100 is then transported into the deposition module 510 for deposition of a semiconductor absorber layer 160 on the halide coated surface 155 of the semiconductor window layer 150, as shown in FIG. 3A, which may be performed by deposition assembly 551, for example, a vapor transport deposition assembly. The photovoltaic device 100 with the semiconductor absorber layer 160 deposited on the halide coated surface 155 of the semiconductor window layer 150 will then proceed through modules 506, 507, 508, 509, which will provide a halide heat treatment of applying a first halide coating to the surface of the photovoltaic device 100, heating the coating, applying a second halide coating to the same surface and heating the second halide coating.

It should be noted that in alternative embodiments, where desired, the modules 504, 506, 507, 508, 509, 510 may be arranged in any desired sequence in the treatment system 550 to produce photovoltaic devices 100 as shown in FIGS. 3B and 3C. An additional heating modules may also be provided in sequence after halide application module 504, if desired, to heat the halide application provided by halide application module 504. It should also be noted that, where desired, alternative embodiments of treatment system 550 may include multiple modules 510, which may be positioned in the treatment system 550 to deposit multiple semiconductor layers with halide coatings in a photovoltaic device 100 as shown in FIG. 4.

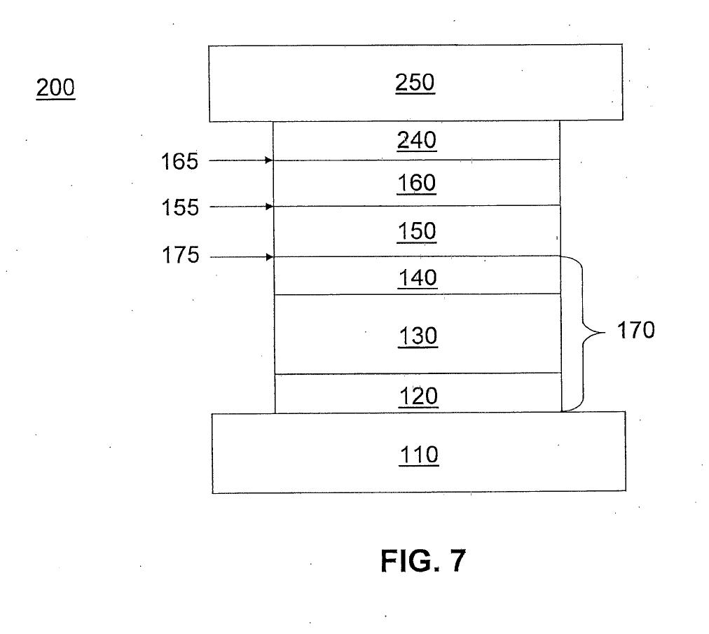

As shown in FIG. 7, semiconductor layers with halide coated surfaces may be incorporated into a photovoltaic device 200. Photovoltaic device 200 may further include a back contact (electrode) 240 deposited adjacent to semiconductor absorber layer 160 and a back support 250, for example, a glass plate, placed adjacent to back contact 240.

The embodiments described above are offered by way of illustration and example. It should be understood that the examples provided above may be altered in certain respects and still remain within the scope of the claims. It should be appreciated that, while the invention has been described with reference to the above embodiments, other embodiments are within the scope of the claims.

What is claimed as new and desired to be protected by Letters Patent of the United States is:

1. A method for producing semiconductor thin-film layers in a photovoltaic device which comprises:
forming a thin-film semiconductor layers over a substrate; and
applying a first halide heat treatment on at least one thin-film layer surface adjacent to or part of the semiconductor layers, wherein the first halide heat treatment comprises:
applying first coating of a halide compound on the at least one surface adjacent to or part of the semiconductor layers;
performing a first heating of the surface after applying the first coating of the halide compound;
applying a second coating of the halide compound on the same surface; and
performing at least a second heating of the surface after applying the second coating of the halide compound.

2. The method of claim 1, wherein forming a thin film semiconductor layers comprises:
forming a semiconductor window layer on the substrate; and
forming a semiconductor absorber layer on the semiconductor window layer.

3. The method of claim 2, wherein the first halide heat treatment is applied on an open surface of the semiconductor absorber layer after it is deposited on the semiconductor window layer.

4. The method of claim 2, wherein the halide compound is at least one of CdCl₂, MnCl₂, MgCl₂, ZnCl₂, NH4Cl, TeCl₄, HCl, or NaCl.

5. The method of claim 2, wherein the temperatures of the first and second heatings of the halide coated surface are between about 300° C. to about 600° C.

6. The method of claim 2, wherein the durations of the first and second heatings of the halide coated surface are between about 10 minutes to about 60 minutes.

7. The method of claim 2, wherein the first and second heatings of the surface comprise flowing a gas at the surface being heated to control the ambient conditions around the surface during the heatings.

8. The method of claim 7, wherein the gas comprises at least an oxygen containing gas, a sulfur containing gas, or an inert gas.

9. The method of claim 2 further comprises:
applying a first pre-coating of the halide compound on the at least one surface adjacent to or part of the semiconductor layers.

10. The method of claim 9, wherein the first pre-coating of the halide compound is applied on an open surface of the semiconductor window layer after it is deposited on the substrate and before the semiconductor absorber layer is deposited; and
wherein the halide heat treatment is applied on the open surface of the semiconductor absorber layer after it is deposited on the semiconductor window layer.

11. The method of claim 9, wherein the first pre-coating of the halide compound is applied on an open surface of the substrate before the semiconductor window layer and the semiconductor absorber layer are deposited; and
wherein the halide heat treatment is applied on the open surface of the semiconductor absorber layer after it is deposited on the semiconductor window layer.

12. The method of claim 9 further comprises:
applying a second pre-coating of the halide compound on the at least one surface adjacent to or part of the semiconductor layers.

13. The method of claim 12, wherein the first pre-coating of the halide compound is applied on an open surface of the substrate before the semiconductor window layer and the semiconductor absorber layer are deposited;
wherein the second pre-coating of the halide compound is applied on an open surface of the semiconductor window layer after it is deposited on the substrate and before the semiconductor absorber layer is deposited; and
wherein the halide heat treatment is applied on the open surface of the semiconductor absorber layer after it is deposited on the semiconductor window layer.

14. The method of claim 2, wherein forming thin film semiconductor layers comprises:
forming a semiconductor window layer over the substrate;
forming a first semiconductor absorber layer on the semiconductor window layer; and
forming a second semiconductor absorber layer on the first semiconductor absorber layer.

15. The method of claim 14 further comprising:
applying a first pre-coating of the halide compound on the at least one surface adjacent to or part of the semiconductor layers; and
applying a second pre-coating of the halide compound on the at least one surface adjacent to or part of the semiconductor layers.

16. An apparatus for forming halide treated semiconductor layers in a photovoltaic device comprising:
a halide heat treatment system for treating a surface of a deposited thin film layer, wherein the halide heat treatment system comprises:
a first halide application module for applying a first coating of halide compound on a surface of a thin-film layer;
a first heating module coupled to the first halide application module for heating the halide coated surface of the thin-film layer;
a second halide application module coupled to the first heating module for applying a second coating of halide compound on the surface of the thin-film layer; and
a second heating module coupled to the second halide application module for heating the halide coated surface of the thin-film layer.

17. The apparatus of claim 16, further comprising a first deposition system coupled to the halide heat treatment system for forming a semiconductor thin-film layer.

18. The apparatus of claim 17 further comprising a conveyor system for transporting a substrate through the halide heat treatment system and the first deposition system.

19. The apparatus of claim 18, wherein the first halide application module comprises a first halide dispenser for applying the first coating of halide compound on the surface of the thin-film layer and the second halide application module comprises a second halide dispenser for applying the second coating of halide compound on the surface of the thin-film layer.

20. The apparatus of claim 18, wherein the first heating module comprises a first heater for heating the halide coated surface of the thin-film layer and the second heating module comprises a second heater for heating the halide coated surface of the thin-film layer.

21. The apparatus of claim 20, wherein the first heating module further comprises a first gas injection port for directing a gas around the halide coated surface of the thin-film layer during heating and the second heating module further comprises a second gas injection port for directing a gas around the halide coated surface of the thin-film layer during heating.

22. The apparatus of claim 21 further comprising a gas curtain system for providing inert gas curtains around the first and second heating modules to maintain the ambient conditions in the first and second heating modules.

23. The apparatus of claim 18 further comprising a second deposition system coupled to the halide heat treatment system for forming a semiconductor thin-film layer,
wherein the first deposition system is couple to the first halide application module for forming a semiconductor thin film layer to be treated by the halide heat treatment system; and
wherein the second deposition system is coupled to the second heating module for forming a semiconductor thin-film layer over a surface that has been treated by the halide heat treatment system.

24. A photovoltaic device comprising:
a substrate;
at least a first semiconductor layer deposited adjacent to the substrate;
an annealed first halide coating on a surface of the first semiconductor layer; and
an annealed second halide coating on the surface of the first semiconductor layer.

25. The photovoltaic device of claim 24 further comprising a TCO layer deposited on the substrate, wherein the first semiconductor layer is deposited on the TCO layer.

26. The photovoltaic device of claim 25, wherein the first semiconductor layer has a grain size greater than or equal to 2 μm.

27. The photovoltaic device of claim 25, wherein the first semiconductor layer is a cadmium telluride layer.

28. The photovoltaic device of claim 27, wherein the halide coatings are at least one of CdCl₂, MnCl₂, MgCl₂, ZnCl₂, NH4Cl, TeCl₄, HCl or NaCl.

29. The photovoltaic device of claim 24 further comprising a second semiconductor layer deposited on the first semiconductor layer.

30. The photovoltaic device of claim 29, wherein the first semiconductor layer is a cadmium sulfide layer and the second semiconductor layer is a cadmium telluride layer.
